(19) United States
(12) Patent Application Publication
(10) Pub. No.: US 2005/0111539 A1
(43) Pub. Date: May 26, 2005

(54) Equalization method and apparatus using the same

(75) Inventor: Seiji Tsuchiya, Osaka (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 10/985,951

(22) Filed: Nov. 12, 2004

(30) Foreign Application Priority Data
Nov. 20, 2003 (JP) 2003-391296

(51) Int. Cl. H03K 5/159

(52) U.S. Cl. 375/229

(57) ABSTRACT

A linear filter unit is provided with a plurality of taps and subjects an equalizer input signal to an equalization process so as to output a filter output signal. A DFE unit is provided with a plurality of taps and subjects the filter output signal to an equalization process according to decision feedback so as to output an equalizer output signal. An LMS algorithm unit computes tap coefficients of the linear filter unit and the DFE unit. A determination unit compares a plurality of received power levels corresponding to a plurality of propagation delays in input delay profile data with a threshold level, selects received power levels equal to or higher than the threshold levels and determines a maximum time corresponding to one of the selected power levels.

### BACKGROUND OF THE INVENTION

1. Field of the Invention

The present invention relates to an equalizing technology and, more particularly, to an equalizing method controlling taps to be used in an equalization process in accordance with the characteristics of radio transmission path, and to a receiver using the method.

2. Description of the Related Art

An adaptive equalizer of a wireless communications system is known as a technology to remove waveform distortion due to multi-path fading occurring in a radio transmission path. An adaptive equalizer is constructed of a matched filter of a transversal type receiving a signal at an input end, a decision feedback equalizer removing intersymbol interference and a demodulator making a determination at an output terminal. A plurality of tap coefficients respectively corresponding to a plurality of taps included in the matched filter are determined by a correlator. A loop filter takes a time average of an output of the correlator for each tap coefficient and fed to a level detector. The level detector compares an output level of the loop filter for each tap coefficient with a threshold level. Control is effected such that the tap corresponding to the tap coefficient for which the output level is equal to or higher than the threshold level is used in the matched filter. The tap corresponding to the tap coefficient for which the output level is lower than the threshold level is not used in the matched filter (see, for example, Reference (1) in the following Related Art List).

### RELATED ARTS LIST

(1) Japanese Patent Application Laid-Open No. 2003-168999.

In an adaptive equalizer in which a filter of a transversal type and a decision feedback equalizer are combined, effects from multi-path transmission occurring in a precursor portion are primarily eliminated by the equalizer of the transversal type and effects from multi-path transmission occurring in a post-cursor portion are primarily eliminated by the decision feedback equalizer. Generally, the number of taps required in an adaptive equalizer depends on a propagation delay occurring in a radio transmission path. That is, the longer the propagation delay, the number of taps required should be increased. Extending this concept to the adaptive equalizer of the aforementioned type, it is desirable that the number of taps in the decision feedback equalizer is controlled depending on a propagation delay of a delay wave. With such control, it is ensured that the number of taps used in an adaptation process is reduced, the processing volume is reduced and power consumption is reduced. When the propagation delay is large, degradation in the received signal quality is prevented by increasing the number of taps.

In an approach whereby the number of taps is controlled by operating or discontinuing the operation of individual taps, the aforementioned control does not necessarily achieve an improvement in the received signal quality if there is a shift between the time when the operation or the discontinuation thereof a tap is determined and the time when the actual equalization process is performed. This is because the radio transmission path and noise power are subject to time-dependent variation. When a plurality of taps included in the equalizer of a transversal type are selected discontinuously, residual errors may build up, thus resulting in degradation in the received signal quality.

### SUMMARY OF THE INVENTION

The present invention has been done in view of the aforementioned circumstances and its object is to provide an equalization method and a receiver using the same, in which a process for determining taps to be used in an equalization process is undertaken easily and accurately in accordance with the characteristics of radio transmission path.

One mode of practicing the present invention is a receiver.

The receiver comprises: a receiving unit receiving a signal via a transmission path; an equalization process unit supplying the received signal to a plurality of taps and subjecting the signal supplied to the plurality of taps to an equalization process; a delay profile estimation unit referring to the received signal to estimate a plurality of received power levels corresponding to a plurality of propagation delays occurring in the transmission path; a determination unit comparing the estimated plurality of received power levels corresponding to the plurality of propagation delays with a predetermined threshold level, so as to determine a propagation delay to be subjected to the equalization process in accordance with a propagation delay corresponding to a received power level equal to or higher than the threshold level, and determining the taps to be used in the equalization process such that taps corresponding to propagation delays equal to or shorter than the propagation delay determined to be subjected to the equalization process are included.

In this receiver, taps to be used in an equalization process are determined so as to cover propagation delays equal to or shorter than a selected delay time corresponding to a received power level in a designated propagation delay profile of the channel higher than a threshold level. Accordingly, it is possible to configure equalization capabilities in accordance with the delay profile.

The determination unit may determine the propagation delay to be subjected to the equalization process, by adding a predetermined period of time to the propagation delay corresponding to the received power level equal to or higher than the threshold level, and determine taps to be used in the equalization process in the plurality of taps, in accordance with the propagation delay determined to be subjected to the equalization process.

The determination unit may computes a measure of variation in the plurality of received power levels corresponding to the plurality of propagation delays and determine the threshold level in accordance with the computed measure of variation.

The equalization process unit may comprise: a front equalization unit supplying the received signal to a group of taps selected from the plurality of taps and subjecting the signal supplied to the group of taps to the equalization process; and a back equalization unit supplying a signal output from the front equalization unit to the rest of the taps, and subjecting the signal supplied to the rest of the taps to a further equalization process, wherein the determination unit determines the number of taps to be used in the equalization process by selecting from the plurality of taps provided in the front equalization unit and the back equalization unit.

The group of taps provided in the front equalization unit may constitute a linear filter, and the rest of the taps in the back equalization unit may constitute a decision feedback

The back equalization unit may comprise a linear filter in addition to the decision feedback equalizer.

Another mode of practicing the present invention is an equalization method.

The equalization method comprises the step of: using an equalizer subjecting a signal received via a transmission path to an equalization process and provided with a plurality of taps, to estimate a plurality of received power levels corresponding to a plurality of propagation delays occurring in a transmission path, to compare the estimated plurality of received power levels corresponding to the plurality of propagation delays with a predetermined threshold level, and to determine taps to be used in the equalization process such that taps corresponding to propagation delays equal to or shorter than a selected delay time corresponding to a received power level equal to or higher than the threshold level are included.

Optional combinations of the aforementioned constituting elements, and implementations of the present invention in the form of methods, apparatuses, systems, recording mediums and computer programs may also be practiced as additional modes of the present invention.

Moreover, this summary of the invention does not necessarily describe all necessary features so that the invention may also be sub-combination of these described features.

### BRIEF DESCRIPTION OF THE DRAWINGS

FIG. 1 shows a construction of a receiver according to a first example.

FIG. 2 shows a burst format in a communication system according to the first example.

FIG. 3 shows a construction of an equalizer of FIG. 1.

FIG. 4 shows a delay profile estimated by a delay profile estimation unit of FIG. 1.

FIG. 5 shows a construction of a linear filter of FIG. 4.

FIG. 6 shows a construction of a DFE unit of FIG. 4.

FIG. 7 shows a construction of an equalizer according to a second example.

FIGS. 8A and 8B shows an outline of a process in a determination unit of FIG. 7.

### DETAILED DESCRIPTION OF THE INVENTION

The invention will now be described based on the following examples which do not intend to limit the scope of the present invention but exemplify the invention. All of the features and the combinations thereof described in the examples are not necessarily essential to the invention.

### FIRST EXAMPLE

A summary of the invention will be given before giving a detailed description. A first example relates to a wireless LAN receiver according to the IEEE802.11b standard. The receiver includes a linear filter and a decision feedback equalizer (hereinafter, referred to as DFE) for an equalization process. A signal output from the linear filter is input to the DFE. The linear filter and the DFE are both constructed as an arrangement of a plurality of taps. The numbers of taps in the linear filter and the DFE are configured such that the DFE is capable of removing a delay wave of a longer propagation delay than that of the wave removed by the linear filter.

When the receiver according to this example receives a burst signal from a transmitter via a radio transmission path, the receiver identifies, by referring to the head of the burst signal, a plurality of received power levels characterized by respective propagation delays incurred in the radio transmission path. That is, the receiver estimates a delay profile. Subsequently, the receiver compares the plurality of received power levels included in a designated delay profile with a predetermined threshold level, so as to identify a received power level characterized by a maximum delay time (hereinafter, referred to as a maximum time) in a plurality of received power levels equal to or higher than the threshold level. The receiver then selects taps to be used in an equalization process so as to include all taps corresponding to propagation delays equal to or shorter than the maximum time. The term “tap” in this case refers to taps included in the linear filter and the DFE. With this construction, it is ensured that a large number of taps are used to eliminate distortion components, when a delay spread in the radio transmission path is relatively extensive. When the delay spread in the radio transmission path is less extensive, a smaller number of taps are used to reduce power consumption. A signal output from the linear filter or the DFE is subject to a CCK demodulation, despreading etc.

As an introduction to the first example of the invention, a brief description will be given of CCK modulation in the IEEE802.11b standard. In CCK modulation, eight bits are grouped as one unit (hereinafter, this unit will be referred to as a CCK modulation unit). The bits will be referred to as d1, d2, . . . d8 in the descending order of digits. The lower six bits in the CCK modulation unit are mapped onto the constellation diagram such that pairs [d3, d4], [d5, d6], [d7, d8] are mapped into the quadrature phase shift keying (QPSK) constellation points, respectively. The mapped phases will be denoted by (φ2, φ3, φ4), respectively. Eight spreading codes P1 through P8 are generated from the phases φ2, φ3, φ4, as given below.
P1=φ2+φ3+φ4
P2=φ3+φ4
P3=φ2+φ4
P4=φ4
P5=φ2+φ3
P6=φ3
P7=φ2
P8=0 (1)

The higher two bits [d1, d2] of the CCK modulation unit are mapped into a constellation point of the differential encoding quadrature shift keying. The mapped phase will be denoted by φ1. φ1 corresponds to a spread signal. Eight chip signals X0 through X7 are generated from the spread signal φ1 and the spreading codes P1 through P8, as given below.
X0=e^{j}(φ1+P1)
X1=e^{j}(φ1+P2)
X2=e^{j}(φ1+P3)
X3=−e^{j}(φ1 +P4)
X4=e^{j}(φ1+P5)
X5=e^{j}(φ1+P6)
X6=−e^{j}(φ1+P7)
X7=e^{j}(φ1+P8) (2)

A transceiver transmits the chip signals X0 through X7 in the stated order (hereinafter, a time sequence unit comprising the chip signals X0 through X7 will also be referred to as a CCK modulation unit).

In addition to using CCK modulation, DBPSK and DQPSK phase modulated signals are spread by known spreading codes and transmitted in the IEEE802.11b standard. The received signal referred to in this example is basically in the form of chip signal.

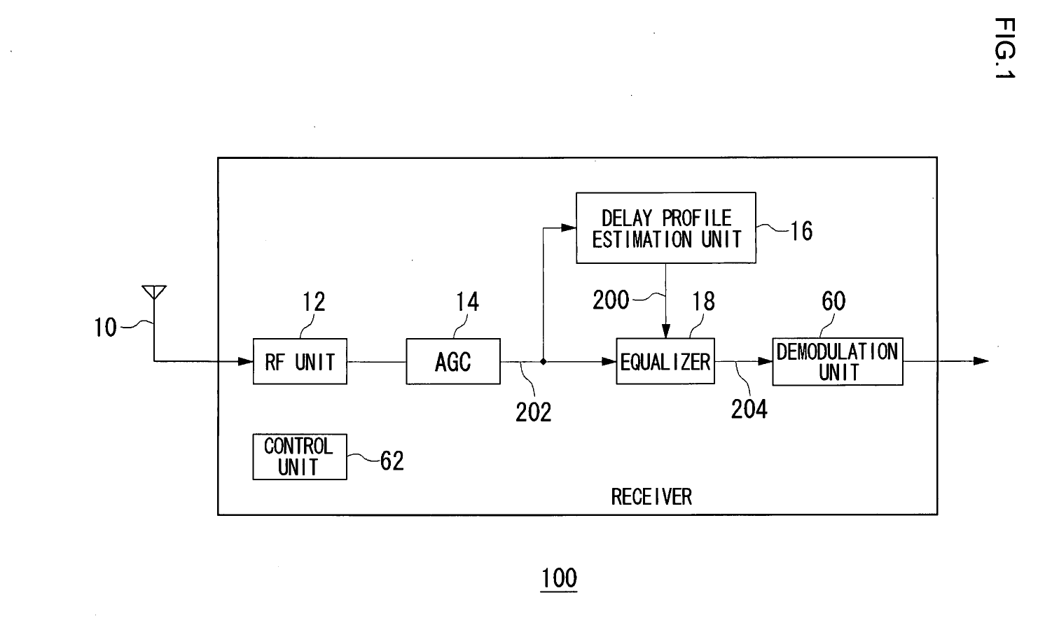

FIG. 1 shows a construction of a receiver 100 according to the first example. The receiver 100 comprises an antenna 10, an RF unit 12, an automatic gain controller (AGC) 14, a delay profile estimation unit 16, an equalizer 18, a demodulation unit 60 and a control unit 62. Signals involved include delay profile data 200, an equalizer input signal 202 and an equalizer output signal 204.

The antenna 10 receives a burst signal at a radio frequency transmitted from a transmitter (not shown).

The RF unit 12 converts the received burst signal at a radio frequency into a burst signal at an intermediate frequency. Further, the RF unit 12 subjects the burst signal at the intermediate frequency to quadrature detection so as to output a base band burst signal. Generally, a base band burst signal is shown to comprise an in-phase component and quadrature component. FIG. 1, however, illustrates it as a composite of the components.

An AGC 14 automatically controls the gain of the base band burst signal so as to fit the amplitude of the base band signal to a dynamic range of an AD converter unit (not shown). The AD converter converts the analog base band signal to a digital signal so as to output a signal composed of a plurality of bits. The signal output from the AGC 14 is indicated as an equalizer input signal 202.

The delay profile estimation unit 16 estimates a delay profile from a base band burst signal. The head of the burst signal is a known signal. For estimation of a delay profile, correlation between the received burst signal and the known signal is computed during the head of the burst signal. The estimated delay profile is output as serial or parallel delay profile data 200.

The equalizer 18 receives the equalizer input signal 202 for an equalization process and outputs an equalizer output signal 204. The construction of the equalizer 18 will be described later. For now, it will be mentioned that the equalizer 18 includes a plurality of taps. A plurality of tap coefficients corresponding the plurality of taps are determined by estimation by the least mean square (LMS) algorithm. Those of the taps that are actually used in an equalization process are determined according to the delay profile data 200.

The demodulating unit 60 demodulates the equalizer output signal 204. If the equalizer output signal 204 is a phase modulated or spread signal, despreading or differential detection is performed. If the equalizer output signal 204 is a CCK modulated signal, CCK demodulation using Walsh transform is performed.

The control unit 62 controls the timing of operation in the receiver 100.

The construction as described above may be implemented by hardware including a CPU, a memory and an LSI and by software including a program provided with reservation and management functions loaded into the memory. FIG. 1 depicts function blocks implemented by a cooperation of the hardware and software. Therefore, it will be obvious to those skilled in the art that the function blocks may be implemented by a variety of manners including hardware only, software only or a combination of both.

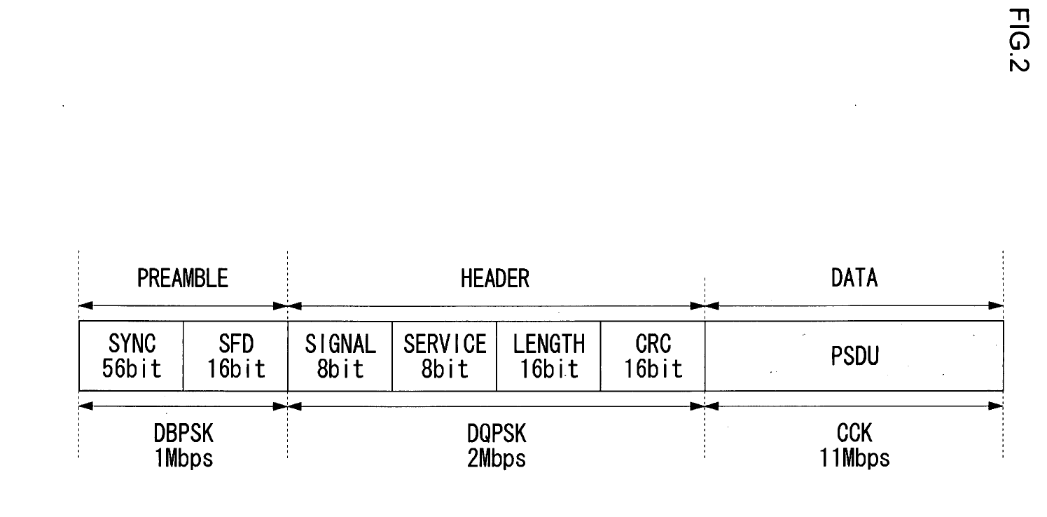

FIG. 2 shows a burst format in a communication system according to the first example. The burst format corresponds to the short PLCP of the IEEE802.11b standard. As illustrated, the burst signal includes preamble, header and data fields. A preamble is transmitted at a transmission rate of 1 Mbps according to the DBPSK modulation scheme. The header is transmitted at a transmission rate of two Mbps according to the DQPSK modulation scheme. The data are transmitted at a transmission rate of 5.5 or 11 Mbps according to the CCK modulation scheme. The preamble includes SYNC of 56 bits and SFD of 16 bits. The header includes SIGNAL of 8 bits, SERVICE of 8 bits, LENGTH of 16 bits and CRC of 16 bits. The length of PSDU corresponding to the data is variable. A preamble corresponds to a known signal referred to for estimation of a delay profile.

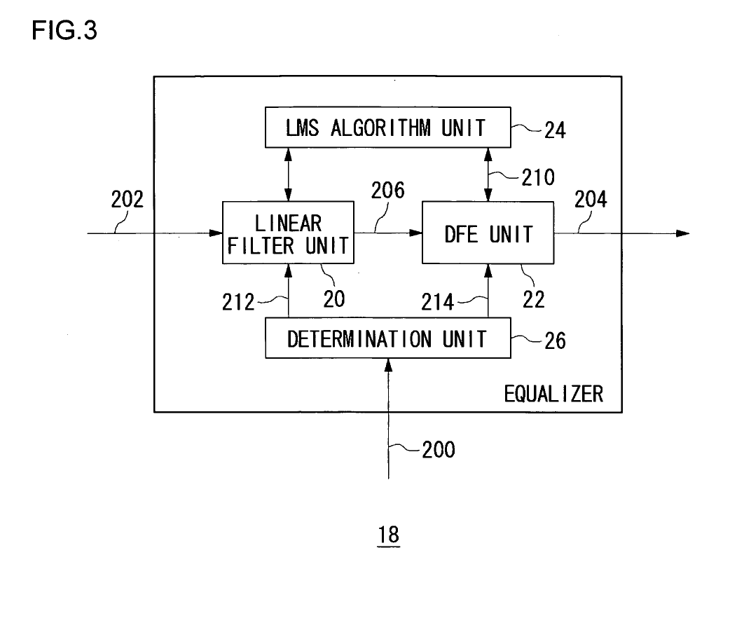

FIG. 3 shows a construction of the equalizer 18. The equalizer 18 includes a linear filter unit 20, a DFE unit 22, an LMS algorithm unit 24 and a determination unit 26. Signals involved include a filter output signal 206, a tap related signal 210, a filter tap control signal 212 and a DFE tap control signal 214.

The linear filter unit 20 is provided with a plurality of taps and outputs the signal 206 by subjecting the equalizer input signal 202 to an equalizing process. A time interval between the plurality of taps provided in the linear filter unit 20 is ½ the time interval of a chip signal. The tap coefficients corresponding to the plurality of taps are determined by computation in the LMS algorithm unit 24 during the head of the burst signal. It is assumed here that the tap coefficient once determined remains unchanged while the burst signal lasts.

The DFE unit 22 is provided with a plurality of taps and outputs the signal 204 by subjecting the filter output signal 206 to an equalization process according to decision feedback. A time interval between the plurality of taps provided in the DFE unit 22 is the same as the time interval of a chip signal. The tap coefficients corresponding to the plurality of taps are determined by computation in the LMS algorithm unit 24 described later, after the tap coefficients of the linear filter unit 20 are determined during the head of the burst. The tap coefficients are updated in the LMS algorithm unit 24 while the burst signal lasts. Signals required to determine and update tap coefficients are transmitted between the LMS algorithm unit 23 and the DFE unit 22 in accordance with the tap related signal 210.

The LMS algorithm unit 24 computes the tap coefficients in the linear filter unit 20 and the DFE unit 22. The coefficients in the linear filter unit 20 are computed in accordance with the equalizer input signal 202 and the known signal. The tap coefficients in the DFE unit 22 are computed in accordance with the known signal or the equalizer output signal 204, and the filter output signal 206.

The determination unit 26 stores a predetermined threshold level and compares a plurality of received power levels constituting the input delay profile 200 and characterized by respective propagation delays, with the threshold level. Received power levels equal to or higher than the threshold level are selected and a maximum time corresponding to one of the selected received power levels is identified. Of the plurality of taps included in the linear filter unit 20, those taps corresponding to propagation delays equal to or shorter than the maximum time are selected as taps to be used in the equalization process. The information related to the selection is output as a filter tap control signal 212. Of the plurality of taps included in the DFE unit 22, those taps corresponding to propagation delays equal to or shorter than the maximum time are selected as taps to be used in the equalization process. The information related to the selection is output as a DFE tap control signal 214. That is, taps are selected such that, the longer the propagation delay, the larger the number of taps used, and the shorter the propagation delay, the smaller the number of taps used. If a tap corresponding to the maximum time is not available, a tap corresponding to a propagation delay one step longer than the maximum time and taps corresponding to propagation delays shorter than the maximum time are selected.

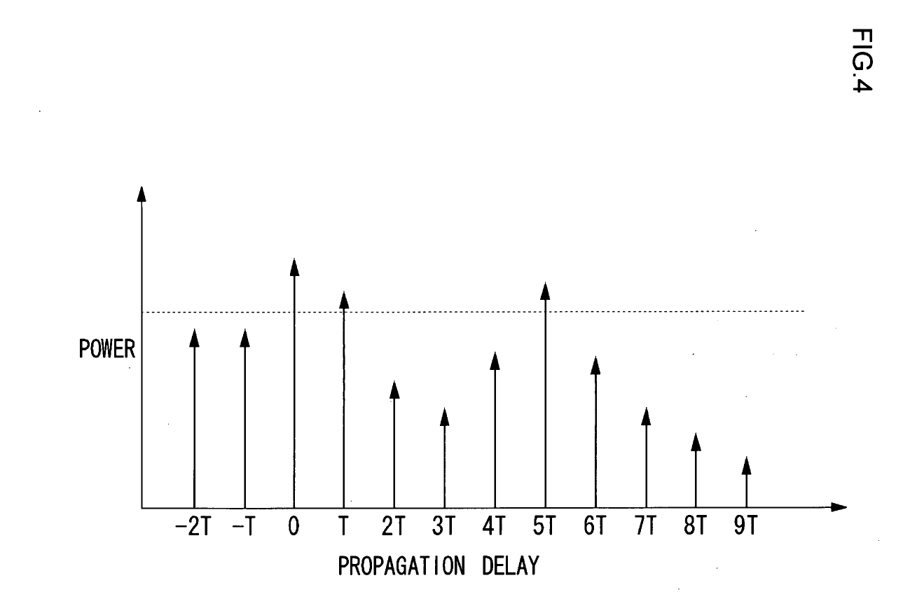

FIG. 4 shows a delay profile estimated by the delay profile estimation unit 16, where the horizontal axis indicates a propagation delay and the vertical axis indicates power. The propagation delay corresponding to a delay component with the highest power is designated as “propagation delay 0”. A propagation delay difference from “propagation delay 0” is indicated by “propagation delay T”, “propagation delay 2T” etc. “T” indicates a time resolution by which delay components of a delay profile are estimated. Normally, the time resolution “T” is set to a sampling period of A/D conversion. The propagation delay difference corresponding to advance waves preceding “propagation delay 0” is designated by “propagation delay −T”, “propagation delay −2T” etc.

The threshold level preset by the determination unit 26 is indicated by a solid line. The determination unit 26 compares the plurality of power levels with the threshold level so as to select power levels equal to or higher than the threshold level. It is assumed that “propagation delay 0”, “propagation delay T” and “propagation delay 5T” are selected. The longest of the propagation delay, i.e. “propagation delay 5T” is selected as the maximum time. The determination unit 26 causes all the taps in a range between “propagation delay −2T” and “propagation delay 5T” in the linear filter unit 20 and the DFE unit 22 to operate.

In addition to the above-described operation, a time, for example 2T, to be added to the maximum time may be predetermined. The maximum time may be updated by adding the preset time to the maximum time determined as described above so that taps to be used in an equalization process are selected in accordance with the maximum time thus updated. That is, the maximum time determined in accordance with the delay profile may be extended by a fixed period of time.

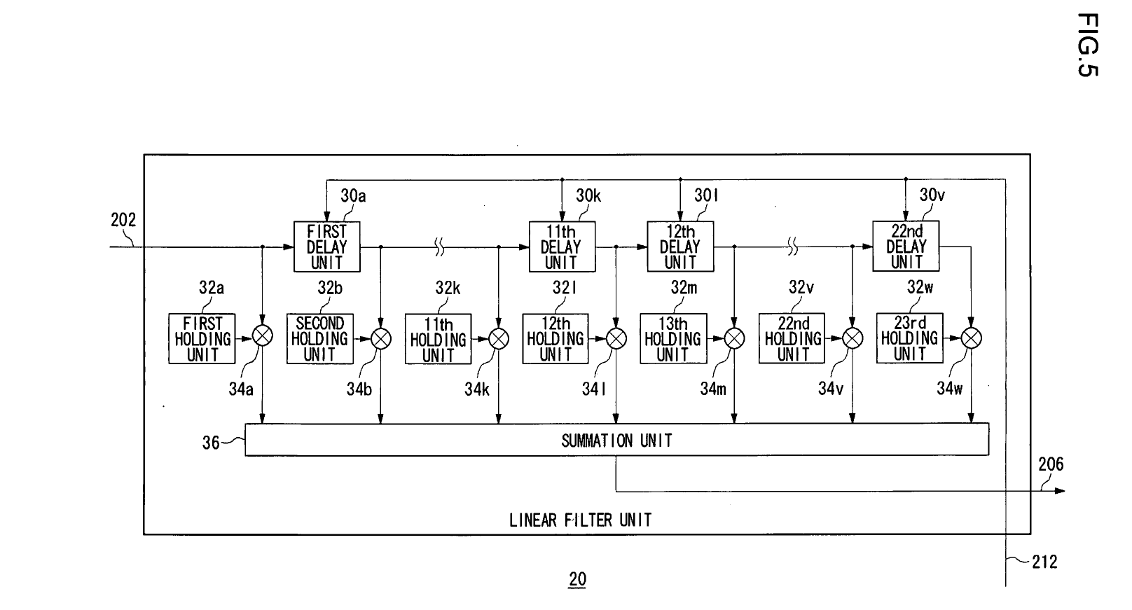

FIG. 5 shows a construction of the linear filter 20. The linear filter 20 comprises a first delay unit 30a, an eleventh delay unit 30k, a twelfth delay unit 301, a twenty-second delay unit 30v, generically referred to as a delay unit 30, a first holding unit 32a, a second holding unit 32b, an eleventh holding unit 32k, a twelfth holding unit 321, a thirteenth holding unit 32m, a twenty-second holding unit 32v, a twenty-third holding unit 32w, generically referred to as a holding unit 32, a first multiplying unit 34a, a second multiplying unit 34b, an eleventh multiplying unit 34k, a twelfth multiplying unit 34l, a thirteenth multiplying unit 34m a thirty-second multiplying unit 34v, a twenty-third multiplying unit 34w, generically referred to as a multiplying unit 24, and a summation unit 36.

The delay unit 30 delays the equalizer input signal 202. A node between two units of the delay unit 30 corresponds to a tap. Since a total of twenty-two units are provided in the delay unit 30 as illustrated, the number of taps is twenty-three. The delay provided by the delay unit 30 is configured to be ½ the time interval of a chip signal.

Individual units of the delay unit 30 to be operated are determined in accordance with the filter tap control signal 212.

Each of the individual units of the holding unit 32 receives the tap coefficient computed by the LMS algorithm unit 24 via a signal line (not shown) and holds the same. As described before, the tap coefficients once stored in the holding unit 32 remain unchanged while the burst signal lasts.

Each of the individual units in the multiplying unit 34 multiplies the signal output from a corresponding unit of the delay unit 30 by the tap coefficient held in a corresponding unit of the holding unit 32. The summation unit 26 computes a total sum of results of multiplication by the multiplying unit 34 so as to output the filter output signal 206.

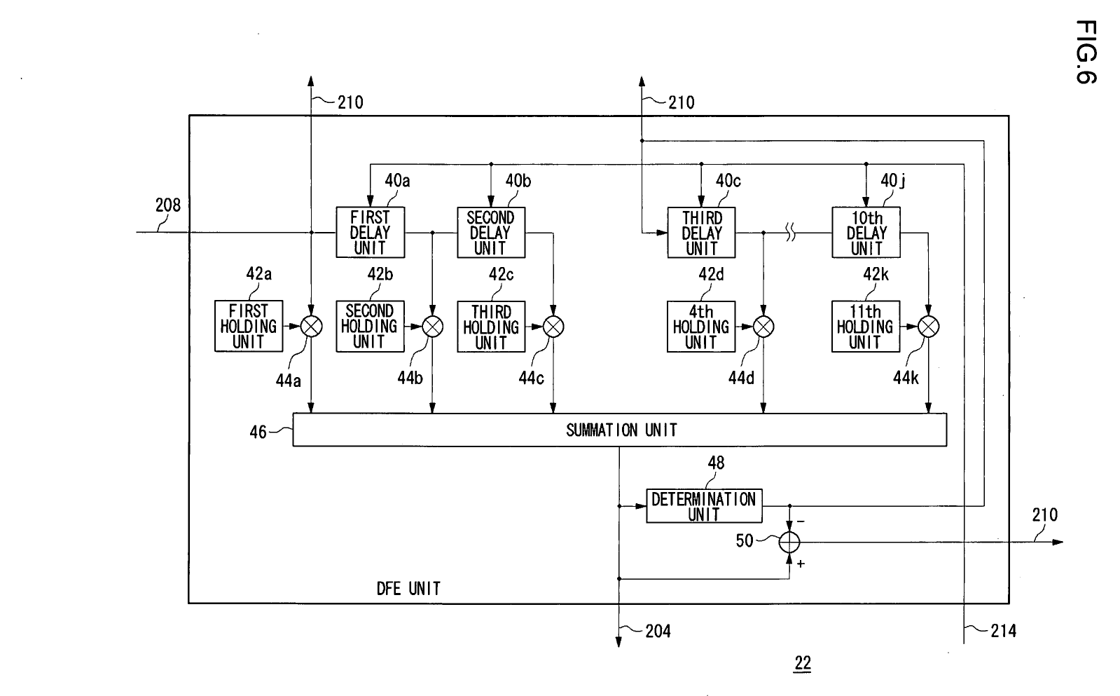

FIG. 6 shows a construction of the DFE unit 22. The DFE unit 22 comprises a first delay unit 40a, a second delay unit 40b, a third delay unit 40c, a tenth delay unit 40j, generically referred to as a delay unit 40, a first holding unit 42a, a second holding unit 42b, a third holding unit 42c, a fourth holding unit 42, an eleventh holding unit 42k, generically referred to as a holding unit 42, a first multiplying unit 44a, a second multiplying unit 44b, a third multiplying unit 44c, a fourth multiplying unit 44d, an eleventh multiplying unit 44k, generically referred to as a multiplying unit 44, a summation unit 46, a determination unit 48 and an adding unit 50.

The delay unit 40 is divided into two parts, a first part being referred to as a feed forward tap unit (hereinafter, referred to as an FF unit) comprising the first delay unit 40a and the second delay unit 40b, and a second part being referred to as a feedback tap unit (hereinafter, referred to as an FB unit) comprising the third delay unit 40c and the tenth delay unit 40j. Nodes preceding, between and succeeding the two delay units in the FF unit correspond to the aforementioned taps. Since there are two delay units provided in the FF unit, there are three taps. In the FB unit, one delay unit corresponds to the aforementioned tap. Since there are eight delay units provided in the FB unit, there are eight taps. The delay provided by the delay unit 40 is configured to be the time interval of a chip signal. Individual units in the delay unit to be operated are determined by the DFE tap control signal 214.

Each of the individual units of the holding unit 42 receives the tap coefficient computed by the LMS algorithm unit 24 via a signal line (not shown) and holds the same. As described before, the tap coefficients to be held in the holding unit 42 are updated while the burst signal lasts.

Each of the individual units in the multiplying unit 44 multiplies the signal output from a corresponding unit of the delay unit 40 by the tap coefficient held in a corresponding unit of the holding unit 42. The summation unit 46 calculates a total sum of results of multiplication by the multiplying unit 44. The determination unit 48 makes a determination on the signal output from the summation unit 46. The signal derived from the determination is output to the LMS algorithm unit 24 as the tap related signal 210 and supplied to the third delay unit 40c.

The adding unit 50 determines an error between the signal output from the summation unit 46 and the signal derived from the determination in the determination unit 48 by subtraction. The adding unit 50 outputs the error to the LMS algorithm unit 24 as the tap related signal 210. The signal output from the summation unit 46 is output as the equalizer output signal 204.

The operation of the receiver 100 with the above construction will be described. The receiver 100 receives a burst signal. The delay profile estimation unit 16 estimates a delay profile by referring to a preamble included in the burst signal. The determination unit 26, determining that the received power level corresponding to propagation delay 5T is equal to or higher than the threshold level, determines that all taps in the linear filter unit 20 and the DFE unit 22 corresponding to propagation delays equal to or shorter than 5T should be operated. In a period of time when the preamble in the burst signal occurs, the LMS algorithm unit 24 computes the tap coefficients of the linear filter unit 20 and subsequently computes the tap coefficients of the DFE unit 22. While the data field in the burst signal occurs, the linear filter unit 20 subjects the data signal to an equalization process so as to output the filter output signal 206, and the DFE unit 22 subjects the filter output signal 206 to an equalization process so as to output the equalization output signal 204. While the data field in the burst signal lasts, the LMS algorithm unit 24 updates the tap coefficients in the DFE unit 22.

According to the first example of the present invention, taps to be used in an equalization process are determined such that propagation delays equal to or shorter than the maximum propagation delay associated with the power levels in a designated delay profile equal to or higher than a predetermined threshold level are covered. Accordingly, tap selection is executable without making any determination on the configuration of an envelope of a delay profile. Even when there are delay waves characterized by long propagation delays, delay components are successively removed as a result of using a larger number of taps. When there are not delay waves characterized by long propagation delays, power consumption is reduced as a result of using a limited number of taps. Since a series of taps comprising a plurality of taps are selected, tap to tap accumulation of residual errors occurring is minimized.

### SECOND EXAMPLE

In the second example of the present invention, taps to be used in an equalization process are determined in accordance with a delay spread estimated by referring to a received signal. Unlike the first example, taps to be used are selected from a plurality of taps included in the linear filter instead of the DFE. Moreover, the threshold level used in determining the taps to be used in an equalization process is modified in accordance with the configuration of delay profile.

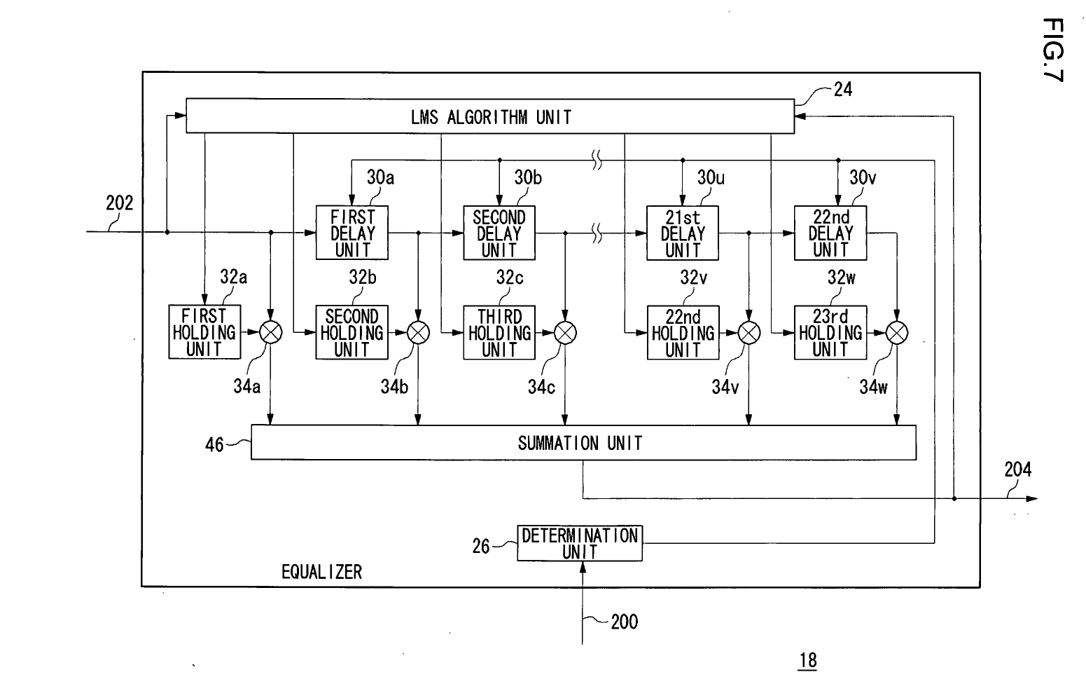

FIG. 7 shows a construction of the equalizer 18 according to the second example. The equalizer 18 of FIG. 7 is constructed such that the DFE unit 22 is removed from the equalizer 18 of FIG. 3. The linear filter unit according to the second example differs from the linear filter unit 20 of FIG. 5 in that there are provided a second delay unit 30b, a twenty-first delay unit 30u, a third holding unit 32c and a third multiplying unit 34c. The operation of the delay unit 30, the holding unit 32 and the multiplying unit 36 is already described so that the description thereof is omitted.

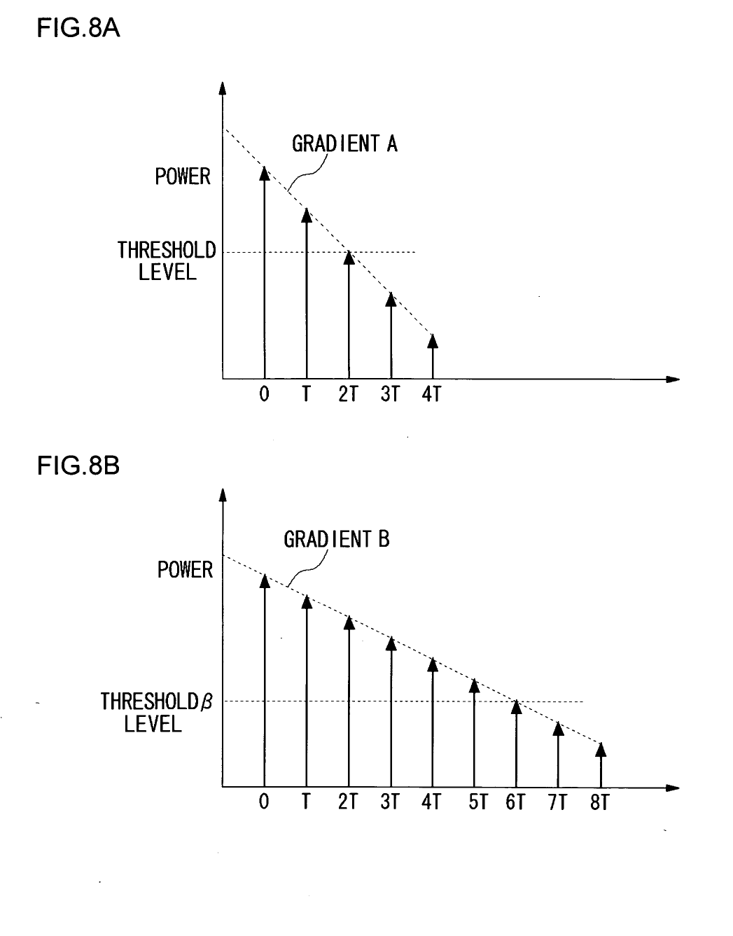

The determination unit 26 stores a predetermined threshold level, like the determination unit 26 of FIG. 4 and compares the input delay profile data 200 with the threshold level. A difference is that the threshold level is varied in accordance with the delay profile data 200. A specific example will now be given by referring to FIGS. 8A and 8B. FIGS. 8A and 8B show an outline of a process in the determination unit 26. The horizontal axis indicates a propagation delay and the vertical axis indicates power, as in FIG. 4. FIG. 8A shows a case where the gradient of an envelope is “A”, and FIG. 8B shows a case where the gradient is “B”, where “A” is greater than “B”. The determination unit 26 establishes a threshold level “α” for the gradient “A” and a threshold level “β” for the gradient “B”, where “α” is greater than “β”. The determination unit 26 compares the threshold level thus determined with the delay profile and configures propagation delay 2T as the maximum time, in the case of FIG. 8A, and configures propagation delay 6T as the maximum time in the case of FIG. 8B.

The greater the gradient of an envelope, the higher the threshold level so that the number of taps to be used in an equalization process is reduced. Delay waves with propagation delays for which taps are not provided in the equalization process affect the received signal quality by causing residual distortion. That is, the higher the power of the entirety of residual distortion, the worse the received signal quality. When the gradient of the envelope of a delay profile is small, reduction in the power of delay waves is limited as the propagation delay is increased. Therefore, it is necessary to use a relatively low threshold level so that the power of residual distortion is controlled. When the gradient of the envelope of a delay profile is large, reduction in the power of delay waves is significant as the propagation delay is increased. Therefore, the power of residual distortion is controlled successfully even when a relatively high threshold level is set.

According to the second example of the present invention, taps to be used in an equalization process are determined considering the configuration of the envelope of a delay profile so that refined control is possible.

Given above is an explanation based on the example of the present invention. The example is only illustrative in nature and it will be obvious to those skilled in the art that variations in constituting elements and processes are possible within the scope of the present invention.

In the first and second examples of the present invention, the receiver 100 is used in wireless LAN that complies with the IEEE802.11b standard. Alternatively, the receiver 100 may be used in a third generation cellular telephone system or in a wireless LAN that complies with another standard such as the IEEE802.11g standard instead of the IEEE802.11b standard. According to the variation, the present invention is applicable to a variety of wireless systems. That is, the present invention is applicable to a wireless system used in an environment in which the characteristics of radio transmission path between a transmitting end and a receiving end is subject to variation.

In the first example of the present invention, a combination of the linear filter unit 20 and the DFE unit 22 is used to constitute the equalizer 18. In the second example of the present invention, the linear filter 20 is used to constitute the equalizer 18. Alternatively, maximum likelihood sequence estimation may be used in the equalizer 18, or a combination of the maximum likelihood sequence estimation and the DFE unit 22 may be used in the equalizer 18. According to this variation, a variety of equalizers may be used to construct the equalizer 18. The type of equalizers used in the equalizer 18 may be selected to adapt to the characteristics of radio transmission path in which the receiver 100 is used.

A combination of the first and second examples may also be useful. According to this variation, the combined advantages from the first and second examples are available.

Although the present invention has been described by way of exemplary examples, it should be understood that many changes and substitutions may further be made by those skilled in the art without departing from the scope of the present invention which is defined by the appended claims.

1. A receiver comprising:
a receiving unit receiving a signal via a transmission path;
an equalization process unit supplying the received signal to a plurality of taps and subjecting the signals supplied to the plurality of taps to an equalization process;
a delay profile estimation unit referring to the received signal to estimate a plurality of received power levels corresponding to a plurality of propagation delays occurring in the transmission path;
a determination unit comparing the estimated plurality of received power levels corresponding to the plurality of propagation delays with a predetermined threshold level, so as to determine a propagation delay to be subjected to the equalization process in accordance with a propagation delay corresponding to a received power level equal to or higher than the threshold level, and determining the taps to be used in the equalization process such that taps corresponding to propagation delays equal to or shorter than the propagation delay determined to be subjected to the equalization process are included.

2. The receiver according to claim 1, wherein said determination unit determines the propagation delay to be subjected to the equalization process, by adding a predetermined period of time to the propagation delay corresponding to the received power level equal to or higher than the threshold level, and determines taps to be used in the equalization process in the plurality of taps, in accordance with the propagation delay determined to be subjected to the equalization process.

3. The receiver according to claim 1, wherein said determination unit computes a measure of variation in the plurality of received power levels corresponding to the plurality of propagation delays and determines the threshold level in accordance with the computed measure of variation.

4. The receiver according to claim 1, wherein said equalization process unit comprises:
a front equalization unit supplying the received signal to a group of taps selected from the plurality of taps and subjecting the signal supplied to the group of taps to the equalization process; and
a back equalization unit supplying a signal output from said front equalization unit to the rest of the taps, and subjecting the signal supplied to the rest of the taps to a further equalization process, wherein
said determination unit determines the number of taps to be used in the equalization process by selecting from the plurality of taps provided in the front equalization unit and said back equalization unit.

5. The receiver according to claim 2, wherein said equalization process unit comprises:
a front equalization unit supplying the received signal to a group of taps selected from the plurality of taps and subjecting the signal supplied to the group of taps to the equalization process; and
a back equalization unit supplying a signal output from said front equalization unit to the rest of the taps, and subjecting the signal supplied to the rest of the taps to a further equalization process, wherein
said determination unit determines the number of taps to be used in the equalization process by selecting from the plurality of taps provided in the front equalization unit and said back equalization unit.

6. The receiver according to claim 3, wherein said equalization process unit comprises:
a front equalization unit supplying the received signal to a group of taps selected from the plurality of taps and subjecting the signal supplied to the group of taps to the equalization process; and
a back equalization unit supplying a signal output from said front equalization unit to the rest of the taps, and subjecting the signal supplied to the rest of the taps to a further equalization process, wherein
said determination unit determines the number of taps to be used in the equalization process by selecting from the plurality of taps provided in the front equalization unit and said back equalization unit.

7. The receiver according to claim 4, wherein the group of taps provided in said front equalization unit constitute a linear filter, and the rest of the taps in said back equalization unit constitute a decision feedback equalizer.

8. The receiver according to claim 5, wherein the group of taps provided in said front equalization unit constitute a linear filter, and the rest of the taps in said back equalization unit constitute a decision feedback equalizer.

9. The receiver according to claim 6, wherein the group of taps provided in said front equalization unit constitute a linear filter, and the rest of the taps in said back equalization unit constitute a decision feedback equalizer.

10. The receiver according to claim 7, wherein said back equalization unit comprises a linear filter in addition to the decision feedback equalizer.

11. The receiver according to claim 8, wherein said back equalization unit comprises a linear filter in addition to the decision feedback equalizer.

12. The receiver according to claim 9, wherein said back equalization unit comprises a linear filter in addition to the decision feedback equalizer.

13. An equalization method comprising the step of:
using an equalizer subjecting a signal received via a transmission path to an equalization process and provided with a plurality of taps, to estimate a plurality of received power levels corresponding to a plurality of propagation delays occurring in a transmission path, to compare the estimated plurality of received power levels corresponding to the plurality of propagation delays with a predetermined threshold level, and to determine taps to be used in the equalization process such that taps corresponding to propagation delays equal to or shorter than a selected delay time corresponding to a received power level equal to or higher than the threshold level are included.
